(19) United States
(12) Patent Application Publication
(10) Pub. No.: US 2021/0062337 A1
(43) Pub. Date: Mar. 4, 2021

(54) EXHAUST PIPE DEVICE

(71) Applicant: Kioxia Corporation, Tokyo (JP)

(72) Inventors: Hiroshi MATSUBA, Fujisawa Kanagawa (JP); Akihiro OISHI, Yokohama Kanagawa (JP); Kazuaki KURIHARA, Yokohama Kanagawa (JP); Hiroyuki FUKUMIZU, Yokohama Kanagawa (JP)

(73) Assignee: Kioxia Corporation, Tokyo (JP)

(21) Appl. No.: 16/781,395

(22) Filed: Feb. 4, 2020

(30) Foreign Application Priority Data
Aug. 28, 2019 (JP) 2019-155280

(51) Int. Cl. C23C 16/44

(52) U.S. Cl. CPC C23C 16/4412

(57) ABSTRACT

An exhaust pipe device according to an embodiment includes a pipe body; a dielectric formed in an annular and disposed along an inner wall of the pipe body; an internal electrode formed in an annular, disposed along an inner wall of the dielectric with a part of an inner wall surface of the dielectric left and configured to expose the part of the inner wall surface of the dielectric left without being disposed to a center side of the pipe body; and a plasma generation circuit configured to generate plasma on an exposed surface of the dielectric by using the internal electrode, wherein the exhaust pipe device functions as a part of an exhaust pipe disposed between a film forming chamber and a vacuum pump for exhausting an inside of the film forming chamber.

### CROSS-REFERENCE TO RELATED APPLICATION

This application is based upon and claims the benefit of priority from Japanese Patent Application No. 2019-155280 filed on Aug. 28, 2019 in Japan, the entire contents of which are incorporated herein by reference.

### FIELD

Embodiments described herein relate generally to an exhaust pipe device.

### BACKGROUND

In a film forming device represented by a chemical vapor deposition (CVD) device, raw material gas is introduced into a film forming chamber and a desired film is formed on a substrate disposed in the film forming chamber. The raw material gas remaining in the film forming chamber is exhausted by a vacuum pump via an exhaust pipe. At that time, products resulting from the raw material gas may be stacked in the exhaust pipe to close the exhaust pipe or the products may be stacked in the vacuum pump on the downstream side of the exhaust pipe to stop the vacuum pump. To remove the stacked products, cleaning processing is performed by a remote plasma source (RPS) device. However, since the RPS device generally focuses on cleaning in the film forming chamber, cleaning performance is insufficient to clean the products stacked in the exhaust pipe near the vacuum pump distant from the RPS device and the vacuum pump.

### BRIEF DESCRIPTION OF THE DRAWINGS

FIG. 1 is a configuration diagram showing an example of a configuration of an exhaust system of a semiconductor fabricating device in a first embodiment;

FIG. 2 is a cross-sectional view of an example of an exhaust pipe device in the first embodiment when viewed from a front direction;

FIG. 3 is a cross-sectional view of an example of the exhaust pipe device in the first embodiment when viewed from a top surface direction;

FIG. 4 is a cross-sectional view of an example of an exhaust pipe device in a second embodiment when viewed from a front direction;

FIG. 5 is a cross-sectional view of an example of the exhaust pipe device in the second embodiment when viewed from a top surface direction;

FIG. 6 is a cross-sectional view of an example of an exhaust pipe device in a third embodiment when viewed from a front direction;

FIG. 7 is a cross-sectional view of an example of the exhaust pipe device in the third embodiment when viewed from a top surface direction;

FIG. 8 is an external view of an example of an internal electrode in a fourth embodiment;

FIG. 9 is a cross-sectional view of an example of an exhaust pipe device in a fifth embodiment when viewed from a front direction;

FIG. 10 is a cross-sectional view of an example of the exhaust pipe device in the fifth embodiment when viewed from a top surface direction;

FIG. 11 is a cross-sectional view of an example of an exhaust pipe device in a sixth embodiment when viewed from a front direction; and

FIG. 12 is a cross-sectional view of an example of an exhaust pipe device in a seventh embodiment when viewed from a front direction.

### DETAILED DESCRIPTION

An exhaust pipe device according to an embodiment includes a pipe body, a dielectric, an internal electrode, and a plasma generation circuit. The dielectric is formed in an annular and disposed along an inner wall of the pipe body. The internal electrode is formed in an annular, disposed along an inner wall of the dielectric with a part of an inner wall surface of the dielectric left and configured to expose the part of the inner wall surface of the dielectric left without being disposed to a center side of the pipe body. The plasma generation circuit is configured to generate plasma on an exposed surface of the dielectric by using the internal electrode. The exhaust pipe device functions as a part of an exhaust pipe disposed between a film forming chamber and a vacuum pump for exhausting an inside of the film forming chamber.

In the following embodiments, an exhaust pipe device capable of removing products stacked in an exhaust pipe near a vacuum pump will be described.

### First Embodiment

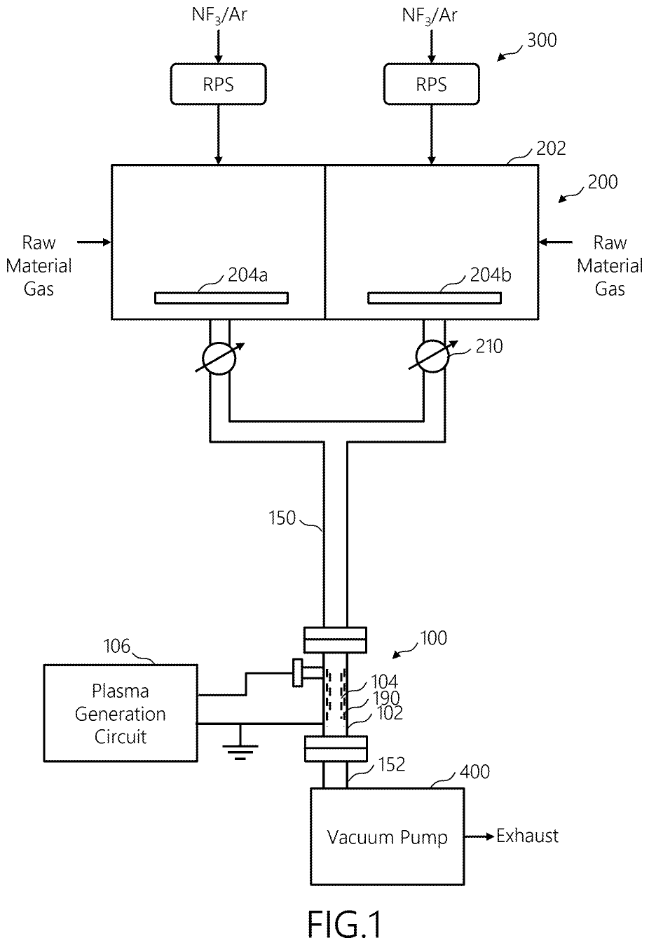

FIG. 1 is a configuration diagram showing an example of a configuration of an exhaust system of a semiconductor fabricating device in a first embodiment. In the example of FIG. 1, a film forming device, for example, a chemical vapor deposition (CVD) device 200 is shown as the semiconductor fabricating device. In the example of FIG. 1, a multi-chamber type CVD device 200 in which two film forming chambers 202 are disposed is shown. In the CVD device 200, semiconductor substrates 204 (204a and 204b) to be film-formed are disposed in the film forming chambers 202 controlled to a desired temperature. In addition, evacuation is performed through exhaust pipes 150 and 152 by a vacuum pump 400 and raw material gas is supplied to the inside of the film forming chamber 202 controlled to a desired pressure by a pressure control valve 210. In the film forming chamber 202, a desired film is formed on the substrate 204 by a chemical reaction of the raw material gas. For example, a silicon oxide film (SiO film) or a silicon nitride film (SiN film) is formed by introducing silane (SiH₄) gas as main raw material gas. In addition, for example, tetraethoxysilane (TEOS) gas or the like is introduced as main raw material gas to form a silicon oxide film (SiO film). When these films are formed, products resulting from the raw material gas are stacked in the film forming chamber 202 and the exhaust pipes 150 and 152. Therefore, in a film forming process cycle, a cleaning step is performed in addition to a film forming step. In the cleaning step, cleaning gas such as nitrogen trifluoride (NF₃) gas or purge gas such as argon (Ar) gas is supplied to remote plasma source (RPS) devices 300 disposed on the upstream side of the film forming chambers 202 and fluorine (F) radicals are generated by plasma. Then, by supplying (diffusing) the F radicals to the inside of the film forming chamber 202 and the side of the exhaust pipe 150, cleaning of the products to be stacked is performed. For example, silicon tetrafluoride (SiF₄) generated after decomposition of the stacked products by cleaning is highly volatile, so that it is exhausted from the vacuum pump 400 through the exhaust pipes 150 and 152.

However, it may be difficult for the F radicals to reach portions of the exhaust pipes 150 and 152 distant from the film forming chamber 202 and cleaning performance may be degraded. In particular, because a pressure is lowered at a position close to a suction port of the vacuum pump 400, a cleaning rate may be lowered. As a result, the exhaust pipes 150 and 152 may be closed by the stacked products. Further, a gap between a rotor and a casing may be filled with the stacked products in the vacuum pump 400 to thereby enter an overload state and the vacuum pump 400 may be stopped. Therefore, in the first embodiment, as shown in FIG. 1, an exhaust pipe device 100 is disposed at a position closer to the suction port of the vacuum pump 400 than the film forming chamber 202.

In FIG. 1, the exhaust pipe device 100 according to the first embodiment is used as a part of an exhaust pipe including the exhaust pipes 150 and 152 disposed between the film forming chamber 202 and the vacuum pump 400 for evacuating the film forming chamber 202. The exhaust pipe device 100 includes a pipe body 102, a dielectric 190, an internal electrode 104, and a plasma generation circuit 106. For the pipe body 102, for example, a pipe material made of the same material as those of the normal exhaust pipes 150 and 152 is used. For example, a stainless steel material such as SUS304 is used. However, from the viewpoint of corrosion resistance against the cleaning gas, an SUS316 steel material is more preferably used as the material of the pipe body 102. Further, for the pipe body 102, for example, a pipe material having the same size as those of the normal exhaust pipes 150 and 152 is used. However, the present disclosure is not limited thereto. For the pipe body 102, a pipe having a size larger than those of the exhaust pipes 150 and 152 may be used. Alternatively, for the pipe body 102, a pipe having a size smaller than those of the exhaust pipes 150 and 152 may be used. Flanges are disposed at both ends of the pipe body 102, one end of the pipe body 102 is connected to the exhaust pipe 150 on which a flange having the same size is disposed, and the other end thereof is connected to the exhaust pipe 152 on which a flange having the same size is disposed. In FIG. 1, illustration of a clamp or the like for fixing the flange of the exhaust pipe device 100 and the respective flanges of the exhaust pipes 150 and 152 is omitted. Hereinafter, the same is applied to the respective drawings. In each of the embodiments to be described below, a case where the exhaust pipe 152 is interposed between the exhaust pipe device 100 and the vacuum pump 400 is shown. However, the present disclosure is not limited thereto. The exhaust pipe device 100 may be disposed directly at the suction port of the vacuum pump 400. The dielectric 190 and the internal electrode 104 are disposed in the pipe body 102. The plasma generation circuit 106 uses the internal electrode 104 to generate plasma by creeping discharge on a surface of the dielectric 190 in the pipe body 102.

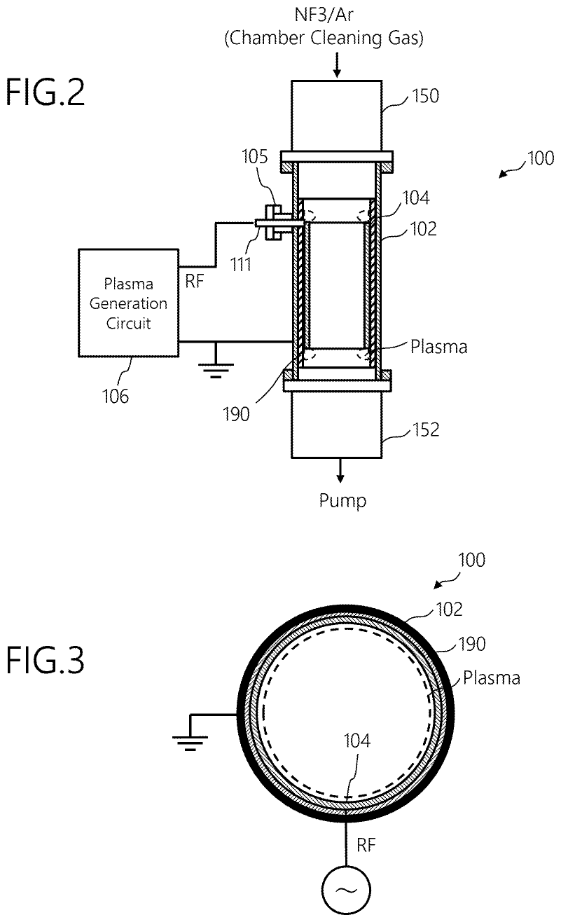

FIG. 2 is a cross-sectional view of an example of the exhaust pipe device in the first embodiment when viewed from a front direction. FIG. 3 is a cross-sectional view of an example of the exhaust pipe device in the first embodiment when viewed from a top surface direction. In FIG. 2, a cross-sectional structure shows the exhaust pipe device 100 and the rest of the structure does not show a cross-section. Hereinafter, the same is applied to each cross-sectional view viewed from the front direction. In FIGS. 2 and 3, the dielectric 190 is formed in the same type of shape as that of the pipe body 102. In the examples of FIGS. 2 and 3, for the cylindrical (annular) pipe body 102 having a circular cross-section, the cylindrical (annular) dielectric 190 having the same type of circular cross-section is used. In addition, for the cylindrical pipe body 102 having a rectangular cross-section, the cylindrical dielectric 190 having the same type of rectangular cross-section may be used. The dielectric 190 is disposed along an inner wall of the pipe body 102. In the examples of FIGS. 2 and 3, the dielectric 190 is disposed in contact with the inner wall of the pipe body 102. The dielectric 190 may be made of a material having a dielectric constant larger than that of air. As the material of the dielectric 190, for example, quartz, alumina (Al₂O₃), yttria (Y₂O₃), hafnia (HfO₂), zirconia (ZrO₂), magnesium oxide (MgO), or aluminum nitride (AlN) is preferably used. A thickness of the dielectric 190 may be appropriately set as long as it does not disturb exhaust performance.

The internal electrode 104 is formed in the same type of shape as that of the dielectric 190. Therefore, the internal electrode 104 is formed in the same type of shape as that of the pipe body 102. In the examples of FIGS. 2 and 3, for the cylindrical dielectric 190 having a circular cross-section, the cylindrical (annular) internal electrode 104 having the same type of circular cross-section is used. In addition, for the cylindrical dielectric 190 having a rectangular cross-section, the cylindrical internal electrode 104 having the same type of rectangular cross-section may be used. The internal electrode 104 is disposed along the inner wall of the dielectric 190 with a part of an inner wall surface of the dielectric 190 left, and the part of the inner wall surface of the dielectric 190 left without being disposed is exposed to the center side of the pipe body 102. In the examples of FIGS. 2 and 3, the internal electrode 104 is disposed in contact with the inner wall of the dielectric 190. As a result, the heat generated in the internal electrode 104 can be released to the dielectric 190 and further from the dielectric 190 to the pipe body 102 by heat conduction. In the examples of FIGS. 2 and 3, a case where the internal electrode 104 is formed shorter than the dielectric 190 in a vertical direction of a plane of paper is shown. As a result, a part of each inner wall surface of the dielectric 190 can be exposed in regions adjacent to upper and lower ends of the internal electrode 104. The part of the inner wall surface of the dielectric 190 may be exposed to only the upper end side of the internal electrode 104. Further, a metal electrode is used as the internal electrode 104. For example, a stainless steel material is used. A material of the internal electrode 104 may be the same material as those of the exhaust pipes 150 and 152. However, similarly to the pipe body 102, an SUS316 material is preferable from the viewpoint of corrosion resistance against the cleaning gas or the like. As the material of the internal electrode 104, aluminum (Al) may also be used. From the viewpoint of corrosion resistance against the cleaning gas or the like, an inner wall surface of the pipe body 102 and/or a surface of the internal electrode 104 is preferably coated with a ceramic material. As the ceramic material, for example, Al₂O₃, Y₂O₃, HfO₂, ZrO₂, MgO, or AlN is preferably used.

In the examples of FIGS. 2 and 3, a case where a radio-frequency (RF) electric field is applied to the internal electrode 104 with the pipe body 102 as a grounded ground electrode is shown. Specifically, an introduction terminal 111 (an example of a radio-frequency introduction terminal) is introduced into the pipe body 102 from an introduction terminal port 105 connected to an outer circumferential surface of the pipe body 102, and the introduction terminal 111 is connected to the internal electrode 104. In FIG. 2, illustration of the introduction terminal port 105 is shown in a simplified manner. Hereinafter, the same is applied to the respective drawings. In addition, the plasma generation circuit 106 applies a radio-frequency (RF) voltage to the internal electrode 104 via the introduction terminal 111 with the pipe body 102 as the grounded ground electrode, thereby applying the radio-frequency electric field between the internal electrode 104 and the pipe body 102 (ground electrode). As a result, plasma is generated by creeping discharge with the upper and lower ends (edges) of the internal electrode 104 as starting points, in the portions exposed to the inside (center axis side) of the pipe body 102 (the portions adjacent to the upper and lower ends of the internal electrode 104), of the inner wall surface of the dielectric 190 between the internal electrode 104 and the pipe body 102. The F radicals by the plasma are generated by using the rest of the cleaning gas such as NF₃ gas supplied from the upstream side by the cleaning step described above. Then, the stacked products in the pipe body 102 are removed by the F radicals. As a result, high cleaning performance can be exerted in the exhaust pipe. For example, SiF₄ generated after decomposition of the stacked products by the F radicals is highly volatile, so that it is exhausted by the vacuum pump 400 through the exhaust pipe 152. Further, a part of the radicals generated by the exhaust pipe device 100 cleans the products stacked in the vacuum pump 400, so that it is possible to reduce a deposition amount of products stacked in the vacuum pump 400. For example, the F radicals generated by the plasma in a part of the inner wall surface of the dielectric 190 exposed to the lower end side of the internal electrode 104 can be caused to enter the vacuum pump 400 with little consumption in the pipe body 102. Further, as described above, since the heat of the internal electrode 104 is easily released, the consumption of F radicals due to an influence of the heat can be reduced, and an amount of F radicals to be used for removing the products can be increased.

As described above, according to the first embodiment, it is possible to remove the products to be stacked in the exhaust pipe near the vacuum pump 400 distant from the film forming chamber 202. Further, the products to be stacked in the vacuum pump 400 can be reduced. Further, it is possible to reduce an installation area of the device for removing the products to be stacked.

### Second Embodiment

In the first embodiment, a configuration for generating plasma by creeping discharge in portions adjacent to upper and lower ends of an internal electrode 104 has been described. However, the present disclosure is not limited thereto. In a second embodiment, a configuration for further increasing a plasma generation region will be described. In addition, points not to be specifically described below are the same as those of the first embodiment.

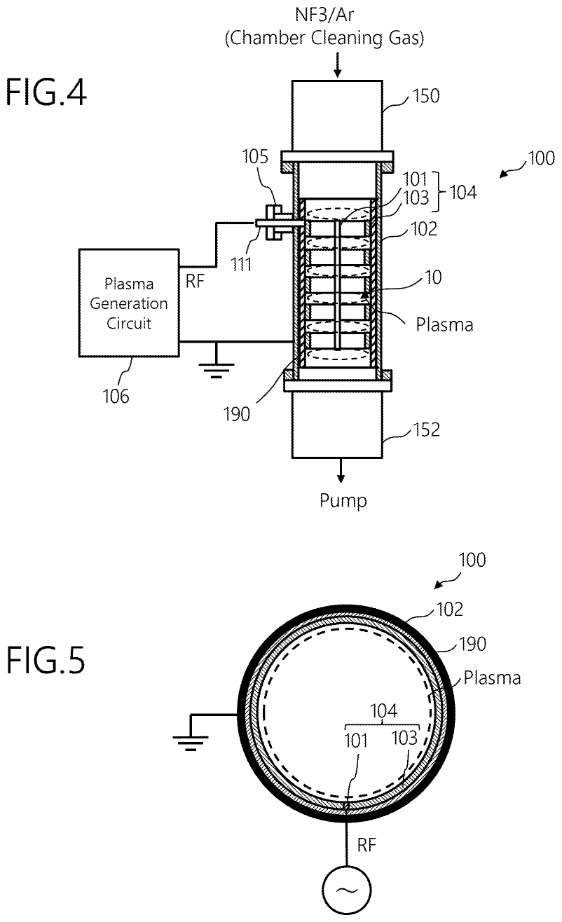

FIG. 4 is a cross-sectional view of an example of an exhaust pipe device in the second embodiment when viewed from a front direction. FIG. 5 is a cross-sectional view of an example of the exhaust pipe device in the second embodiment when viewed from a top surface direction. In FIG. 4, at least one opening 10 is formed in a surface of the internal electrode 104. In FIGS. 4 and 5, the internal electrode 104 has a support rod 101 and a plurality of annular electrodes 103. In FIGS. 4 and 5, the plurality of annular electrodes 103 are fixed and supported by the support rod 101 extending in a vertical direction of a plane of paper (a direction in which gas flows) with a gap in the vertical direction of the plane of paper. The plurality of annular electrodes 103 may be supported by one support rod 101, or the plurality of annular electrodes 103 may be supported by two or more support rods 101. For example, the plurality of annular electrodes 103 may be supported by two support rods 101 disposed at positions where phases are shifted by 180 degrees. Alternatively, for example, the plurality of annular electrodes 103 may be supported by three support rods 101 disposed at positions where phases are shifted by 120 degrees. As a result, the horizontally long opening 10 extending in a direction orthogonal to the gas flow from the side of a film forming chamber 202 is formed along the surface of the internal electrode 104. For example, the rectangular opening 10 is formed. Alternatively, at least one opening 10 may be formed by cutting out the surface of the cylindrical internal electrode 104 and forming a horizontally long slit. By forming at least one opening 10, it is possible to increase the number and area of portions exposed to the inside (center axis side) of a pipe body 102, of an inner wall surface of a dielectric 190.

The plurality of annular electrodes 103 in the internal electrode 104 are formed in the same type of shape as that of the dielectric 190. In the examples of FIGS. 4 and 5, for the cylindrical dielectric 190 having a circular cross-section, the plurality of cylindrical (annular) electrodes 103 having the same type of circular cross-section are used. In addition, for the cylindrical dielectric 190 having a rectangular cross-section, the plurality of cylindrical annular electrodes 103 having the same type of rectangular cross-section may be used. The internal electrode 104 is disposed along an inner wall of the dielectric 190 with a part of an inner wall surface of the dielectric 190 left. In the examples of FIGS. 4 and 5, the plurality of annular electrodes 103 are disposed in contact with the inner wall of the dielectric 190. As a result, the heat generated in the internal electrode 104 can be released to the dielectric 190 and further from the dielectric 190 to the pipe body 102 by heat conduction.

In the examples of FIGS. 4 and 5, a case where a radio-frequency (RF) electric field is applied to the internal electrode 104 with the pipe body 102 as a grounded ground electrode is shown. Specifically, as described above, an introduction terminal 111 (an example of a radio-frequency introduction terminal) is introduced into the pipe body 102 from an introduction terminal port 105 connected to an outer circumferential surface of the pipe body 102, and the introduction terminal 111 is connected to the internal electrode 104. In addition, the plasma generation circuit 106 applies a radio-frequency (RF) voltage to the internal electrode 104 via the introduction terminal 111 with the pipe body 102 as the grounded ground electrode, thereby applying the radio-frequency electric field between the internal electrode 104 and the pipe body 102 (ground electrode). For example, by connecting the introduction terminal 111 to the support rod 101, a radio-frequency (RF) voltage can be efficiently applied to the entire portion of the plurality of annular electrodes 103. As a result, plasma is generated by creeping discharge with the ends (edges) of the internal electrode 104 as starting points, in the portions exposed to the inside (center axis side) of the pipe body 102, of the inner wall surface of the dielectric 190 between the internal electrode 104 and the pipe body 102.

In the second embodiment, plasma is generated by creeping discharge with the upper and lower ends (edges) of the plurality of annular electrodes 103 as starting points, in the exposed portion in each opening 10 in addition to the exposed portions in the upper and lower ends of the internal electrode 104. As a result, the plasma generation region can be increased. If the number of annular electrodes 103 increases, the number of openings 10 and the number of upper and lower ends (edges) of the annular electrodes 103 can be increased, so that plasma generation starting points increase, and the plasma generation region can be further increased. Moreover, by adjusting the number of annular electrodes 103, the plasma generation region can be freely adjusted and expanded. If the electrodes are too close to each other, it becomes difficult to perform discharging, so that the size of the opening 10 between the adjacent annular electrodes 103 is preferably in the cm order. Further, even if the number of openings 10 is increased and a facing area between the internal electrode 104 to be an RF electrode and the pipe body 102 to be a ground electrode is reduced, the plasma can be generated by the creeping discharge. The F radicals by the plasma are generated by using the rest of the cleaning gas such as NF₃ gas supplied from the upstream side by the cleaning step described above. Then, the stacked products in the pipe body 102 are removed by the F radicals. As a result, high cleaning performance can be exerted in the exhaust pipe. For example, SiF₄ generated after decomposition of the stacked products by the F radicals is highly volatile, so that it is exhausted by the vacuum pump 400 through the exhaust pipe 152. Further, a part of the radicals generated by the exhaust pipe device 100 cleans the products stacked in the vacuum pump 400, so that it is possible to reduce a deposition amount of products stacked in the vacuum pump 400. Further, as described above, since the heat of the internal electrode 104 is easily released, the consumption of F radicals due to an influence of the heat can be reduced, and an amount of F radicals to be used for removing the products can be increased.

As described above, according to the second embodiment, the plasma generation region can be increased as compared with the first embodiment. Therefore, a generation amount of F radicals can be increased, and the products stacked in the exhaust pipe can be further removed. Further, if the generation amount of F radicals increases, the F radicals entering the vacuum pump 400 increase, so that the products stacked in the vacuum pump 400 can be further reduced.

### Third Embodiment

In the second embodiment, a configuration for forming a rectangular opening 10 extending in a direction orthogonal to the gas flow from the side of a film forming chamber 202 along a surface of an internal electrode 104 has been described. However, the present disclosure is not limited thereto. In a third embodiment, a configuration using the internal electrode 104 in which different openings are formed will be described. In addition, points not to be specifically described below are the same as those of the second embodiment.

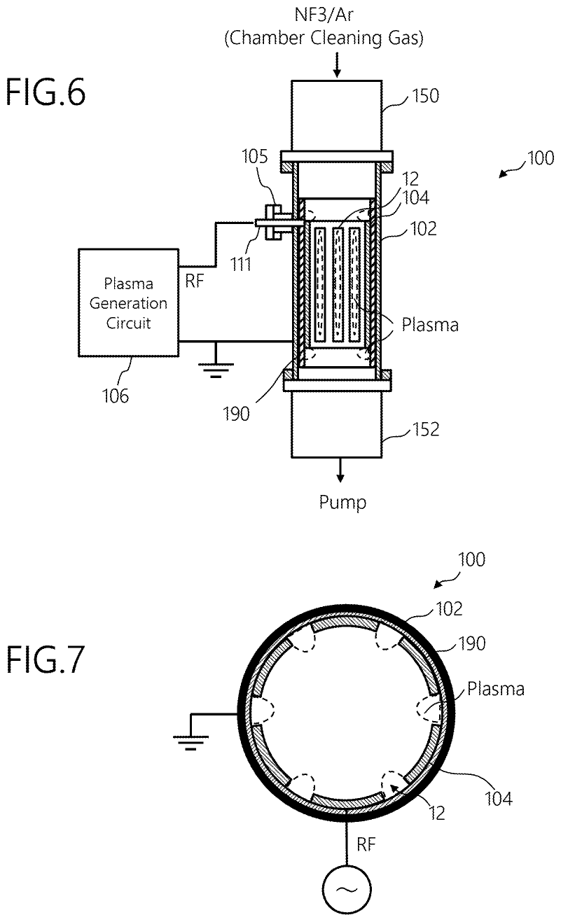

FIG. 6 is a cross-sectional view of an example of an exhaust pipe device in the third embodiment when viewed from a front direction. FIG. 7 is a cross-sectional view of an example of the exhaust pipe device in the third embodiment when viewed from a top surface direction. In FIG. 6, the internal electrode 104 is disposed along an inner wall of a dielectric 190 with a part of an inner wall surface of the dielectric 190 left. In the examples of FIGS. 6 and 7, the internal electrode 104 is disposed in contact with the inner wall of the dielectric 190. As a result, the heat in the internal electrode 104 can be released to the dielectric 190 and further from the dielectric 190 to the pipe body 102 by heat conduction. At least one opening 12 is formed in a surface of the internal electrode 104. In FIGS. 6 and 7, at least one rectangular opening 12 extending in a direction (vertical direction of a plane of paper) parallel to the gas flow from the side of the film forming chamber 202 is formed along the surface of the cylindrical internal electrode 104. The vertically long opening 12 is formed by cutting out the surface of the cylindrical internal electrode 104. For example, the rectangular opening 12 is formed. By forming at least one vertically long opening 12, it is possible to increase the number and area of portions exposed to the inside (center axis side) of the pipe body 102, of the inner wall surface of the dielectric 190. In the examples of FIGS. 6 and 7, a case where six openings 12 are formed is shown. Alternatively, the internal electrode 104 may be configured so that a plurality of arc-shaped electrodes (not shown) are fixed and supported while a phase is shifted with a gap in a circumferential direction, using two support rings (not shown) as upper and lower ends. For example, the two arc-shaped electrodes disposed at positions where phases are shifted by 180 degrees may be supported by the support rings. Alternatively, for example, the six arc-shaped electrodes disposed at positions where phases are shifted by 60 degrees may be supported by the support rings. In this case, the plurality of arc-shaped electrodes are disposed along the inner wall of the dielectric 190. Further, the plurality of arc-shaped electrodes are disposed in contact with the inner wall of the dielectric 190, for example. As a result, the heat in the internal electrode 104 can be released to the dielectric 190 and further from the dielectric 190 to the pipe body 102 by heat conduction. The plurality of arc-shaped electrodes may be fixed to only one of the upper end side and the lower end side by one support ring. In this case, the opening 12 formed between the two adjacent arc-shaped electrodes has a shape in which the side not provided with the support ring is opened.

In the examples of FIGS. 6 and 7, plasma is generated by creeping discharge with ends (edges) forming an outline of each opening 12 in the internal electrode 104 as starting points, in the exposed portion in each opening 12 in addition to the exposed portions in the upper and lower ends of the internal electrode 104. As a result, the plasma generation region can be increased. By increasing the number of openings 12 and the number of ends (edges) forming the outline of each opening 12, plasma generation starting points increase, and the plasma generation region can be further increased. Moreover, by adjusting the number of openings 12, the plasma generation region can be freely adjusted and expanded. If the electrodes are too close to each other, it becomes difficult to perform discharging, so that the size of the opening 12 between the adjacent portions of the internal electrode 104 is preferably in the cm order. Further, even if the number of openings 12 is increased and a facing area between the internal electrode 104 to be an RF electrode and the pipe body 102 to be a ground electrode is reduced, the plasma can be generated by the creeping discharge.

As described above, according to the third embodiment, similarly to the second embodiment, the plasma generation region can be increased as compared with the first embodiment. Therefore, a generation amount of F radicals can be increased, and the products stacked in the exhaust pipe can be further removed. Further, if the generation amount of F radicals increases, the F radicals entering the vacuum pump 400 increase, so that the products stacked in the vacuum pump 400 can be further reduced.

### Fourth Embodiment

In the second and third embodiments, a case where elongated openings are formed in a surface of an internal electrode 104 has been described. However, the present disclosure is not limited thereto. In a fourth embodiment, a configuration using the internal electrode 104 in which different openings are formed will be described. In addition, points not to be specifically described below are the same as those of the second embodiment.

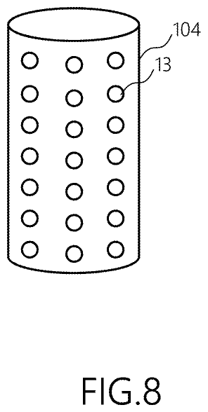

FIG. 8 is an external view of an example of the internal electrode in the fourth embodiment. In the example of FIG. 8, the cylindrical (annular) internal electrode 104 in which a plurality of circular openings 13 are formed is shown. The circle includes an ellipse in addition to a perfect circle. The plurality of openings 13 are formed by punching, for example. Even in this configuration, plasma can be generated by creeping discharge in portions of a dielectric 190 exposed by the plurality of openings 13. If the electrodes are too close to each other, it becomes difficult to perform discharging, so that the diameter size of the opening 13 is preferably in the cm order.

### Fifth Embodiment

In the embodiments described above, a configuration in which a radio-frequency electric field is applied between an internal electrode 104 and a pipe body 102 has been described. However, the present disclosure is not limited thereto. In a fifth embodiment, a configuration in which the internal electrode 104 is divided into two parts and the radio-frequency electric field is applied between the two internal electrodes 104 will be described. In addition, points not to be specifically described below are the same as those of the first embodiment.

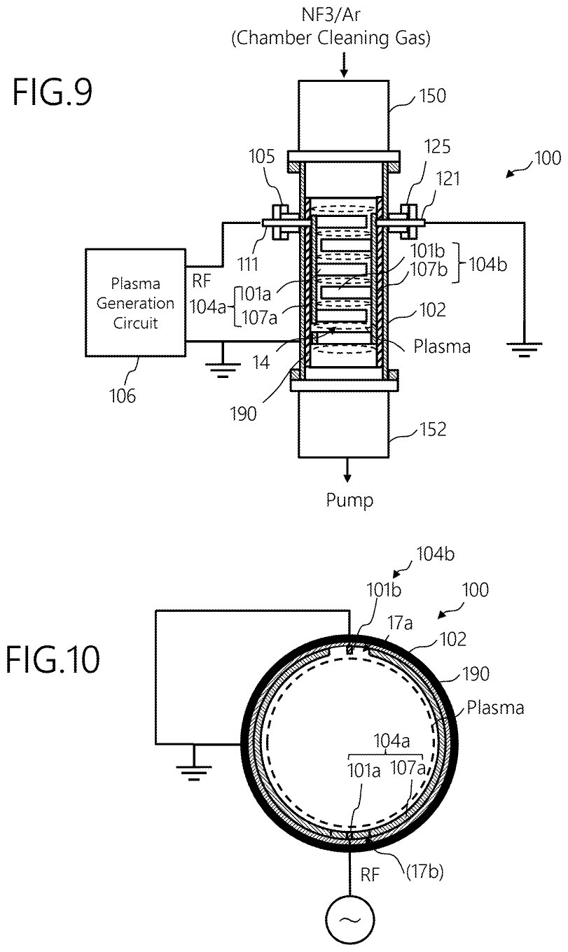

FIG. 9 is a cross-sectional view of an example of an exhaust pipe device in the fifth embodiment when viewed from a front direction. FIG. 10 is a cross-sectional view of an example of the exhaust pipe device in the fifth embodiment when viewed from a top surface direction. In FIG. 9, two internal electrodes 104a and 104b are disposed so as to cover a part of an inner wall of the pipe body 102. Here, similarly to the first embodiment, a dielectric 190 is disposed along the inner wall of the pipe body 102, and the internal electrodes 104a and 104b cover a part of the pipe body 102 with the dielectric 190 therebetween. As a result, an inner wall surface of the dielectric 190 is exposed to the center side of the pipe body 102 between the internal electrodes 104a and 104b. The internal electrode 104a has a support rod 101a and a plurality of arc-shaped electrodes 107a (first internal electrodes) each formed in an arc shape. The plurality of arc-shaped electrodes 107a are fixed and supported by the support rod 101a extending in a vertical direction of a plane of paper in FIG. 9 (a direction in which gas flows) with a gap (opening 14) in the vertical direction of the plane of paper. For example, the arc-shaped electrode 107a is supported by the support rod 101a at, for example, a center portion (a position equidistant from both ends) on an arc. The internal electrode 104b has a support rod 101b and a plurality of arc-shaped electrodes 107b (second internal electrodes) each formed in an arc shape. The plurality of arc-shaped electrodes 107b are fixed and supported by the support rod 101b extending in a vertical direction of a plane of paper in FIG. 9 (a direction in which gas flows) with a gap in the vertical direction of the plane of paper. For example, the arc-shaped electrode 107b is supported by the support rod 101b at, for example, a center portion (a position equidistant from both ends) on an arc. The plurality of arc-shaped electrodes 107a and the plurality of arc-shaped electrodes 107b are alternately disposed in the vertical direction of the plane of paper without contacting each other.

Further, as shown in FIG. 10, each arc-shaped electrode 107a is formed with a gap (opening 17a) in a portion interfering with the support rod 101b, when the internal electrodes 104a and 104b are disposed in combination. In other words, each arc-shaped electrode 107a is formed in an annular shape in which only the portion interfering with the support rod 101b is cut out. Similarly, each arc-shaped electrode 107b is formed with a gap (opening 17b) in a portion interfering with the support rod 101a, when the internal electrodes 104a and 104b are disposed in combination. The plurality of arc-shaped electrodes 107a and the plurality of arc-shaped electrodes 107b are disposed so as to cover a part of the inner wall of the pipe body 102. In the examples of FIGS. 9 and 10, the plurality of arc-shaped electrodes 107a and the plurality of arc-shaped electrodes 107b are disposed in contact with the inner wall of the dielectric 190. As a result, the heat in the internal electrode 104a (and the internal electrode 104b) can be released to the dielectric 190 and further from the dielectric 190 to the pipe body 102 by heat conduction. The plurality of arc-shaped electrodes 107a and the plurality of arc-shaped electrodes 107b are alternately disposed in the vertical direction of the plane of paper without contacting each other, so that a part of the inner wall surface of the dielectric 190 can be exposed in each of gap regions between the arc-shaped electrodes 107a and the arc-shaped electrodes 107b adjacent to each other. If the number of the plurality of arc-shaped electrodes 107a and the plurality of arc-shaped electrodes 107b increases, it is possible to increase the number and area of portions exposed to the inside (center axis side) of the pipe body 102, of the inner wall surface of the dielectric 190.

In FIGS. 9 and 10, a case where with the radio-frequency (RF) electric field is applied between the plurality of arc-shaped electrodes 107a and the plurality of arc-shaped electrodes 107b with one of the plurality of arc-shaped electrodes 107a and the plurality of arc-shaped electrodes 107b as the ground electrode is shown. In the examples of FIGS. 9 and 10, a case where a radio-frequency (RF) voltage is applied to the plurality of arc-shaped electrodes 107a with the plurality of arc-shaped electrodes 107b as the ground electrode is shown. Specifically, as described above, an introduction terminal 111 (an example of a radio-frequency introduction terminal) is introduced into the pipe body 102 from an introduction terminal port 105 connected to an outer circumferential surface of the pipe body 102, and the introduction terminal 111 is connected to the internal electrode 104a. Further, an introduction terminal 121 is introduced into the pipe body 102 from an introduction terminal port 125 connected to the outer circumferential surface of the pipe body 102, and the introduction terminal 121 is connected to the internal electrode 104b. The introduction terminal 121 is grounded. In addition, a plasma generation circuit 106 applies the radio-frequency (RF) voltage to the plurality of arc-shaped electrodes 107a via the introduction terminal 111 with the plurality of arc-shaped electrodes 107b as the ground electrode, thereby applying the radio-frequency electric field between the plurality of arc-shaped electrodes 107a and the plurality of arc-shaped electrodes 107b. For example, by connecting the introduction terminal 111 to the support rod 101a, the radio-frequency (RF) voltage can be efficiently applied to the entire portion of the plurality of arc-shaped electrodes 107a. Further, for example, by connecting the introduction terminal 121 to the support rod 101b, the entire portion of the plurality of arc-shaped electrodes 107b can be efficiently grounded. As a result, plasma is generated by creeping discharge with the ends (edges) of the arc-shaped electrodes 107a and the arc-shaped electrodes 107b as starting points in the exposed portions in the regions between the arc-shaped electrodes 107a and the arc-shaped electrodes 107b, of the inner wall surface of the dielectric 190. In other words, in each of the regions between the plurality of arc-shaped electrodes 107a and the plurality of arc-shaped electrode 107b, the dielectric 190 is exposed to the center side of the pipe body 102, and the plasma is generated by the creeping discharge on the surface of the dielectric exposed in each region.

Further, in the examples of FIGS. 9 and 10, the pipe body 102 is also a ground electrode. As a result, the radio-frequency (RF) electric field is also applied between the plurality of arc-shaped electrodes 107a and the pipe body 102, and the plasma is generated by the creeping discharge with the upper and lower ends (edges) of the internal electrode 104a as starting points in the exposed portions in the upper and lower ends of the internal electrode 104a, of the inner wall surface of the dielectric 190. Further, a plasma generation region can be increased by alternately disposing the arc-shaped electrodes 107a to be the radio-frequency electrode and the arc-shaped electrodes 107b to be the ground electrode. This is particularly effective when the thickness of the dielectric 190 is large and the electric field with the pipe body 102 to be the ground electrode of an outer wall becomes weak. If the number of arc-shaped electrodes 107a and arc-shaped electrodes 107b increases, the number of openings 14 and the number of upper and lower ends (edges) of the arc-shaped electrodes 107a and 107b can be increased, so that plasma generation starting points increase, and the plasma generation region can be further increased. Moreover, by adjusting the number of arc-shaped electrodes 107a and arc-shaped electrodes 107b, the plasma generation region can be freely adjusted and expanded. If the electrodes are too close to each other, it becomes difficult to perform discharging, so that the size of the opening 14 between the arc-shaped electrode 107a and the arc-shaped electrode 107b adjacent to each other is preferably in the cm order.

As described above, according to the fifth embodiment, since both the radio-frequency (RF) electrode and the ground electrode are disposed in the pipe body 102, it is possible to easily perform discharging. Further, similarly to the second embodiment, the plasma generation region can be increased as compared with the first embodiment. Therefore, a generation amount of F radicals can be increased, and the products stacked in the exhaust pipe can be further removed. Further, if the generation amount of F radicals increases, the F radicals entering the vacuum pump 400 increase, so that the products stacked in the vacuum pump 400 can be further reduced.

### Sixth Embodiment

In the embodiments described above, a configuration in which a pipe body 102 is grounded and used as a ground electrode has been described. However, the present disclosure is not limited thereto. In a sixth embodiment, a configuration in which a ground electrode is disposed separately from an internal electrode 104 will be described. In addition, points not to be specifically described below are the same as those of the first to fifth embodiments.

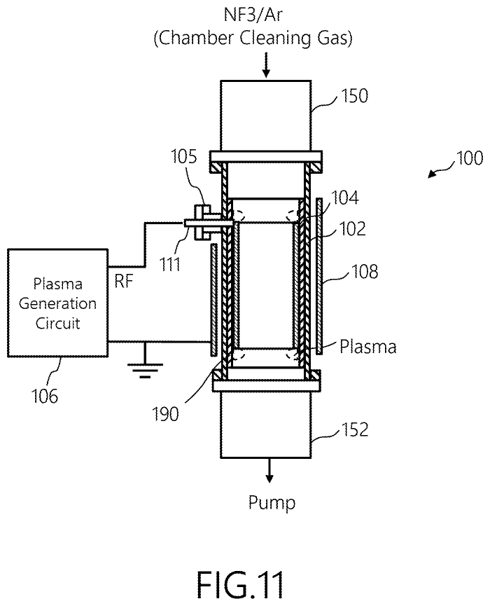

FIG. 11 is a cross-sectional view of an example of an exhaust pipe device in the sixth embodiment when viewed from a front direction. In FIG. 11, a grounded ground electrode 108 is disposed outside the pipe body 102. In FIG. 11, the ground electrode 108 is formed in the same type of shape as that of the pipe body 102. For example, for the pipe body 102 having a circular cross-section, the ground electrode 108 having the same type of circular cross-section is used. In addition, for the pipe body 102 having a rectangular cross-section, the ground electrode 108 having the same type of rectangular cross-section may be used. By taking the same type of cross-sectional shape, in other words, a similar shape, it is possible to cause a distance of a space between the pipe body 102 and the ground electrode 108 to be substantially constant or to approximate to be constant. A material of the ground electrode 108 may be the same material as those of exhaust pipes 150 and 152. Alternatively, the material of the ground electrode 108 may be other conductive material. Since the ground electrode 108 is disposed outside the pipe body 102, corrosion resistance may be lower than that of the internal electrode 104. The rest of the structure is identical to that of FIG. 2. In the example of FIG. 11, in order to cause the pipe body 102 to function as a discharge tube, for example, quartz, Al₂O₃, Y₂O₃, HfO₂, ZrO₂, MgO, or AlN is preferably used as the material of the pipe body 102, without using a metal material. In the example of FIG. 11, a case where the pipe body 102 itself is a dielectric is shown, and a case where a dielectric 190 is further disposed on an inner wall surface of the pipe body 102 similarly to the first to fifth embodiments is shown.

An introduction terminal 111 is introduced into the pipe body 102 from an introduction terminal port 105 connected to an outer circumferential surface of the pipe body 102, and the introduction terminal 111 is connected to the internal electrode 104. In addition, a plasma generation circuit 106 applies a radio-frequency (RF) voltage to the internal electrode 104, thereby applying the radio-frequency electric field between the internal electrode 104 and the ground electrode 108. As a result, as described above, plasma is generated by creeping discharge in exposed portions of the inner wall surface of the dielectric 190. The F radicals by the plasma are generated by using the rest of the cleaning gas such as NF₃ gas supplied from the upstream side by the cleaning step described above. Then, the stacked products in the pipe body 102 are removed by the F radicals.

In the example of FIG. 11, a case where the internal electrode 104 shown in the first embodiment is used is shown. However, the present disclosure is not limited thereto. The same is applied to the case where the internal electrode 104 according to any one of the second to fourth embodiments is used. Further, if a configuration in which an introduction terminal 121 is introduced into the pipe body 102 from an introduction terminal port 125 connected to the outer circumferential surface of the pipe body 102 and the introduction terminal 121 is connected to an internal electrode 104b is used, the same may be applied to the fifth embodiment. When the same is applied to the fifth embodiment, in each region between a plurality of arc-shaped electrodes 107a and a plurality of arc-shaped electrodes 107b, a part of the dielectric 190 is exposed to the center side of the pipe body 102, and the plasma is generated by the creeping discharge on the surface of the dielectric exposed in each region. In this case, the ground electrode 108 may be removed.

As described above, according to the sixth embodiment, in addition to the effects of any one of the first to fifth embodiments, even when the ground electrode 108 is not in contact with the dielectric 190, the plasma can be generated by the creeping discharge.

### Seventh Embodiment

In the sixth embodiment described above, a case where a dielectric 190 is further disposed on an inner wall surface of a pipe body 102 to be a dielectric has been described. However, the present disclosure is not limited thereto.

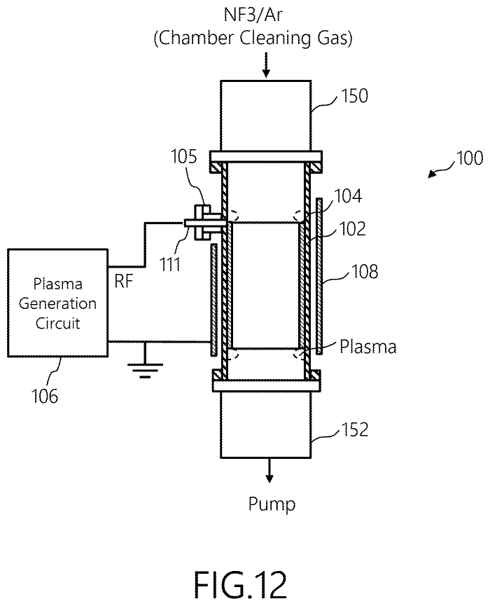

FIG. 12 is a cross-sectional view of an example of an exhaust pipe device in a seventh embodiment when viewed from a front direction. FIG. 12 is the same as FIG. 11 except that the dielectric 190 is removed and an internal electrode 104 is disposed along the inner wall surface of the pipe body 102 to be the dielectric. In addition, points not to be specifically described below are the same as those of the sixth embodiment. In the example of FIG. 12, a case where the internal electrode 104 shown in the first embodiment is used is shown. However, the present disclosure is not limited thereto. The same is applied to the case where the internal electrode 104 according to any one of the second to fourth embodiments is used. Further, if a configuration in which an introduction terminal 121 is introduced into the pipe body 102 from an introduction terminal port 125 connected to the outer circumferential surface of the pipe body 102 and the introduction terminal 121 is connected to an internal electrode 104b is used, the same may be applied to the fifth embodiment. When the same is applied to the fifth embodiment, in each region between a plurality of arc-shaped electrodes 107a and a plurality of arc-shaped electrodes 107b, a part of the inner wall surface of the pipe body 102 to be the dielectric is exposed to the center side of the pipe body 102, and plasma is generated by creeping discharge on a surface of the dielectric exposed in each region. In this case, the ground electrode 108 may be removed.

As described above, according to the seventh embodiment, in addition to the effects of any one of the first to sixth embodiments, even when the dielectric 190 is not disposed on the inner wall surface of the pipe body 102, the pipe body 102 itself becomes the dielectric, and the plasma can be generated by the creeping discharge on the inner wall surface.

The embodiments have been described with reference to the specific examples. However, the present disclosure is not limited to these specific examples.

In addition, all exhaust pipe devices including the elements of the present disclosure and capable of being appropriately design-changed by those skilled in the art are included in the scope of the present disclosure.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. An exhaust pipe device comprising:
a pipe body;
a dielectric formed in an annular and disposed along an inner wall of the pipe body;
an internal electrode formed in an annular, disposed along an inner wall of the dielectric with a part of an inner wall surface of the dielectric left and configured to expose the part of the inner wall surface of the dielectric left without being disposed to a center side of the pipe body; and
a plasma generation circuit configured to generate plasma on an exposed surface of the dielectric by using the internal electrode,
wherein the exhaust pipe device functions as a part of an exhaust pipe disposed between a film forming chamber and a vacuum pump for exhausting an inside of the film forming chamber.

2. The device according to claim 1, wherein at least one opening is formed in a surface of the internal electrode.

3. The device according to claim 2, wherein the at least one opening is formed in a shape extending in a direction parallel or orthogonal to a gas flow from a side of the film forming chamber.

4. The device according to claim 2, wherein the part of the inner wall surface of the dielectric is exposed to the at least one opening of the internal electrode.

5. The device according to claim 1, wherein the internal electrode includes:
a support rod; and
a plurality of annular electrodes supported by the support rod.

6. The device according to claim 5, wherein
the support rod extends in a first direction parallel to a gas flow from a side of the film forming chamber, and
the plurality of annular electrodes are supported by the support rod with a gap in the first direction each other.

7. The device according to claim 6, wherein the part of the inner wall surface of the dielectric is exposed to the gap.

8. The device according to claim 1, wherein
the internal electrode is formed shorter than the dielectric in a first direction parallel to a gas flow from a side of the film forming chamber, and
the part of the inner wall surface of the dielectric is exposed to a region adjacent to an end of the internal electrode in the first direction.

9. The device according to claim 1, wherein the plasma generation circuit uses the pipe body as a ground electrode connected to a ground and applies a radio-frequency electric field between the internal electrode and the ground electrode.

10. The device according to claim 1, further comprising a ground electrode connected to a ground and disposed outside the pipe body, wherein
the plasma generation circuit applies a radio-frequency electric field between the internal electrode and the ground electrode.

11. The device according to claim 10, wherein the pipe body is a dielectric.

12. An exhaust pipe device comprising:
a pipe body which is a dielectric;
an internal electrode formed in an annular, disposed along an inner wall of the dielectric with a part of an inner wall surface of the dielectric left and configured to expose the part of the inner wall surface of the dielectric left without being disposed to a center side of the pipe body; and
a plasma generation circuit configured to generate plasma in an exposed surface of the dielectric by using the internal electrode,
wherein the exhaust pipe device functions as a part of an exhaust pipe disposed between a film forming chamber and a vacuum pump for evacuating the film forming chamber.

13. The device according to claim 12, further comprising a ground electrode connected to a ground and disposed outside the pipe body, wherein
the plasma generation circuit applies a radio-frequency electric field between the internal electrode and the ground electrode.

14. The device according to claim 12, wherein the part of the inner wall surface of the dielectric is exposed to a region adjacent to an end of the internal electrode in a direction parallel to a gas flow from a side of the film forming chamber.

15. An exhaust pipe device comprising:
a pipe body;
a plurality of first electrodes disposed to cover a part of an inner wall of the pipe body;
a plurality of second electrodes alternately disposed in a non-contact manner with the plurality of first electrodes to cover another part of the inner wall of the pipe body; and
a plasma generation circuit configured to use one of the plurality of first electrodes and the plurality of second electrodes as ground electrodes connected to a ground, and generate plasma in each region between the plurality of first electrodes and the plurality of second electrodes by applying a radio-frequency electric field between the plurality of first electrodes and the plurality of second electrodes, wherein,
in the each region between the plurality of first electrodes and the plurality of second electrodes, a dielectric is exposed to a center side of the pipe body, and the exhaust pipe device functions as a part of an exhaust pipe disposed between a film forming chamber and a vacuum pump for evacuating the film forming chamber.

16. The device according to claim 15, further comprising an annular dielectric disposed along the inner wall of the pipe body, wherein
the dielectric which is exposed to the center side is a part of the annular dielectric.

17. The device according to claim 15, wherein
the pipe body is a dielectric, and
the dielectric which is exposed to the center side is a part of the pipe body.

18. The device according to claim 15, wherein each of the plurality of first electrodes and each of the plurality of second electrodes are formed in an arc shape.

19. The device according to claim 18, wherein the plurality of first electrodes formed in the arc shape is supported by one of a first support rod and a second support rod each extending in a direction parallel to a gas flow from a side of the film forming chamber and the plurality of second electrodes formed in the arc shape is supported by another one of the first support rod and the second support rod.

20. The device according to claim 16, wherein the plasma generation circuit uses the pipe body as a ground electrode connected to the ground and further applies a radio-frequency electric field between another one of the plurality of first electrodes and the plurality of second electrodes and the ground electrode.
